(19) United States
(12) Patent Application Publication
(10) Pub. No.: US 2020/0379022 A1
(43) Pub. Date: Dec. 3, 2020

(54) SYSTEM AND METHOD FOR PREVENTING THEFT OF ELECTRICITY

(71) Applicant: Victor Patton, Grass Valley, CA (US)

(72) Inventor: Victor Patton, Grass Valley, CA (US)

(21) Appl. No.: 16/997,734

(22) Filed: Aug. 19, 2020

Related U.S. Application Data
(63) Continuation-in-part of application No. 15/614,344, filed on Jun. 5, 2017, now abandoned.

(51) Int. Cl. G01R 22/06; G01R 11/24; G06Q 50/06; G01R 19/25

(52) U.S. Cl. CPC G01R 22/066; G01R 19/2513; G06Q 50/06; G01R 11/24

(57) ABSTRACT

An electric utility metering system for preventing theft of electricity is disclosed. Theft is prevented by making the meter inaccessible to the customer. Generally, theft of electricity is accomplished by a customer electrically bypassing the meter. Theft therefore is prevented where the customer cannot realistically access the meter. Under the present invention, the meter, and the meter socket (if any) are suspended in a service span between the public utility electric service source and the public utility customer unit. In an alternative embodiment, the meters may be encased in a cabinet or simply placed in a housing with the transformer. Where a cabinet is used, the cabinet may be placed underground, or it may be adjacent to the transformer.

### BACKGROUND OF THE DISCLOSURE

### Technical Field of the Disclosure

The present embodiment relates generally to a method for combatting electricity theft from meters, and more particularly, to a system and method for detecting when electrical meters have been tampered with to prevent the theft of electricity from meters with electric meter housings using a remotely read electrical meter.

### Description of the Related Art

Electrical energy is an important form of energy for human's survival and development, so an adequate amount of power supply is critical for power system operation and development. With the increase in the cost of electricity there has been a corresponding increase in the tampering of electrical supply meters to steal electricity. The different types of electrical power theft include connecting load to power lines before the electrical meter, and thieves can also bypass the meter altogether. Other methods include altering the connections to the meter or tampering with the operation of the meter itself; external wiring modifications and tampering with the meter's internal operation with a strong magnet. A powerful magnet placed next to a meter can saturate the sensor magnetic cores and introduce large errors in measurement, or even disable the meter completely by interfering with its power-supply transformer.

The advent of so-called “smart meters” has exacerbated the problem of theft of electricity. A smart meter is an electronic device that records consumption of electric energy in intervals of an hour or less and communicates that information at least daily back to the utility for monitoring and billing. Smart meters enable two-way communication between the meter and the central system. Unlike home energy monitors, smart meters can gather data for remote reporting. Such an advanced metering infrastructure differs from traditional automatic meter reading in that it enables two-way communications with the meter.

Smart meters benefit public utility companies and other electricity provider greatly by saving on the labor that used to be required to travel to each customer building, read each traditional meter, record a reading, and report the reading back to the public utility company. However, smart meters also come with a major drawback. They make it much easier for customers to get away with theft of electricity. This is because there is no regular monitoring of the customers meter and surrounding area. Using a traditional manual reading system, the utility employee is likely to spot an irregularity (such as wiring routed around the meter!) that might indicate that theft is occurring.

Marijuana growers are notorious culprits when it comes to electricity theft. They are users of substantial power for their growing operations, and because they are sometimes already breaking the law, they are less likely to be deterred.

FIG. 1 illustrates a prior art of a conventional electric utility metering system 50 having a plurality of customer units attached to a public utility electric source 52. The plurality of customer units 56 is attached to the public utility electric source 52 by means of a transformer 54. From the prior art illustrated in FIG. 1, it is understood that theft of electricity can occur and there is no means to detect and prevent the theft of electricity reaching the plurality of customer units 56.

A wide variety of electricity theft prevention systems and methods are currently available. One such device prevents the use of jumpers or other devices for shunting the electrical current around a meter so that the current can be secured without registering on the meter. However in the use of this theft prevention mechanism, a voltage reducing device, is arranged so that any attempt to use jumpers will result in supplying a higher voltage to the load wires than they are supposed to carry, with the result that connected electrical devices can be burned out or otherwise damaged by the excessive current.

Another existing electrical current theft prevention means provides a composite sheath for an electrical wire, so that when the insulation coverings for a plurality of wires are disturbed by tampering, the current supply circuit is immediately, automatically disconnected. Although disconnecting the circuit prevents theft of electric power by blocking current supply, the cost of the composite sheath is high and must be coated to a large area of the plurality of wires to prevent theft.

Certain other existing methods fail to provide a cost-effective electric theft prevention system. Attempts have been made to overcome these problems by developing a disposable tamper detection device for electrical meters of the type with a meter housing with current-carrying blades protruding therefrom for insertion into a meter socket. However, as this device is attached to the meter socket, a thief can still easily tamper with the meter in various ways to steal power.

Therefore, there is a need for a method and system that would prevent theft of electrical energy. Such a system and method would position the meter on a high electric power pole and thus prevent tampering of the meter by thieves. Such a system and method would be cost effective and can be easily employed to prevent electricity theft by intruders. Such a system and method would also prevent any attempt to use jumpers and prevent damage of connected electrical devices from excessive current. The present embodiment overcomes the existing shortcomings in this area by accomplishing these objectives.

### SUMMARY OF THE DISCLOSURE

To minimize the limitations found in the prior art, and to minimize other limitations that will be apparent upon the reading of the specification, the preferred embodiment of the present invention provides an electric utility metering system and method for preventing the theft of electricity.

The electric utility metering system comprises a public utility electric service source, a transformer embedded with a meter and electrically connected to the public utility electric service source, a plurality of public utility customer units connected to the public utility electric service source utilizing a plurality of service wires and a theft monitoring server. The transformer embedded with the meter is electrically connected to the public utility electric service source via an overhead power lines supported by an electric power pole. The meter is positioned inside a housing having a plurality of bolts and a plurality of connecting wires molded into it. The plurality of bolts is employed to attach the housing having the meter with the plurality of service wires or to attach the housing with the electric power pole when needed. The plurality of connecting wires is employed for attaching the housing with the transformer or with the plurality of service wires. The meter is configured to record the total electric power before distribution to each of the plurality of public utility customer units. The meter is a smart meter and records consumption of electrical energy for definite intervals of time and communicates that information to the theft monitoring server. The plurality of public utility customer units is configured to measure the quantity of electricity utilized by each of the customers. Each of the plurality of public utility customer units includes a standard service meter to measure or record the amount of electricity utilized by each customer unit. The meter may also be a smart meter and sends meter readings to the theft monitoring server.

The theft monitoring server can be a general-purpose computer located somewhere on the premises or remotely and is programmed with software that is used to detect and prevent the theft of electricity. The electric utility metering system includes the theft monitoring server residing on a central computer having a processor installed with a theft monitoring application and coupled with a memory unit integrated with a central database. The theft monitoring server comprises a data receiving module, a summation module, a comparison module and a decision module located at the processor of the theft monitoring system. The data receiving module is configured to receive and store meter readings from the meter and the standard service meter on each of the plurality of public utility customer units. The summation module is configured to add the meter readings received from the standard service meter on each of the plurality of public utility customer units to get a total power consumed by the plurality of public utility customer units. The comparison module is configured to compare the meter readings from the master meter with the total power consumed by the plurality of public utility customer units. The comparison module compares the meter readings from the master meter with the total power consumed. The decision module is configured to provide a decision on whether the theft of electricity occurred or not.

The method to detect and prevent the theft of electricity comprises embedding a meter on a transformer connected to a public utility electric service source through an electric power pole. Connecting a plurality of public utility customer units to the transformer, each of the plurality of public utility customer units having a standard service meter. Providing the theft monitoring server installed with the theft monitoring application which is in communication with the master meter and the standard service meter. Then receiving the meter readings from the master meter and the standard service meter on each of the plurality of public utility customer units and storing it on the data receiving module. Adding the meter readings received from the standard service meter on each of the plurality of public utility customer units to get a total power consumed by the plurality of public utility customer units by the summation module. Comparing the meter readings of the master meter with the total power consumed by the plurality of public utility customer units by the comparison module. Providing a decision on whether the theft of electricity occurred or not by the decision module.

It is a first objective of the present invention to provide a method and system that would prevent theft of electrical energy.

A second objective of the present invention is to provide a system and method would position the meter on a high electric power pole and thus prevent tampering of the meter by thieves.

A third objective of the present invention is to provide a system and method would be cost effective and can be easily employed to prevent electricity theft by intruders.

Another objective of the present invention is to provide a system and method would also prevent any attempt to use jumpers and prevent damage of connected electrical devices from excessive current. An alternative embodiment electric utility metering system comprises a public utility electric service source, a transformer, a meter socket, a service meter (“meter”) and a plurality (one or more) of public utility customer units operatively connected to the public utility electric service source. The meter socket is a standard meter socket used in the industry. The meter and meter socket are suspended in a service span between the transformer and a customer unit. For example, the meter socket can have attachment points to accept structural wires (e.g. ground, neutral, support). Further, the meter socket can employ conductor wires or other attachment points to accept the wires that conduct electricity to the customer unit.

Another embodiment of a specialty meter is designed for use in the middle of a service span (“mid service span”). The specialty meter is installed mid service span and includes an attachment point to secure the meter to a structural wire. Attachment points or strain wires can be employed to connect structural wires under physical load or strain by splicing, crimping, preforms, or similar hardware. The specialty meter can also employ attachment points or conductor wires to accept the wires that conduct electricity to the customer unit. Along the service span, specialty meters can be installed for each customer unit.

Another embodiment of a specialty meter designed for mid service span use resembles a “clamshell” and encloses the service wire. The clamshell specialty meter can be affixed (clamped) around the service wire and measure voltage directly from the electrical conductor wires. One implementation for measuring voltage and electrical current can include the specialty meter piercing through insulation around the electrical conductor wires. Another implementation for measuring the electrical current can include measuring the magnetic field around the conductor wires. One of the advantages of the clamshell specialty meter is the ease of installation, because it can be clamped directly over any location of the service wire along the service span.

As another alternative embodiment, an underground electric utility metering system can be employed for the prevention the theft of electricity. The service wires from the transformer are routed under the ground surface and connect to meters encased in a cabinet, which may optionally be located underground. The meter can be a smart meter enabling automated reading or it can be a meter that requires visual reading by opening the cabinet. Preferably, the meters are encased in a cabinet, which may optionally be located underground. The cabinet enclosing the meters could be located in the same housing as the transformer.

These and other advantages and features of the present invention are described with specificity so as to make the present invention understandable to one of ordinary skill in the art.

### BRIEF DESCRIPTION OF THE FIGURES

Elements in the figures have not necessarily been shown to scale in order to enhance their clarity and improve understanding of these various elements and embodiments of the invention. Furthermore, elements that are known to be common and well understood to those in the industry are not depicted in order to provide a clear view of the various embodiments of the invention, thus the figures are generalized in form in the interest of clarity and conciseness.

The foregoing summary as well as the following detailed description of the preferred embodiment of the present invention will be best understood when considered in conjunction with the accompanying figures, wherein like designations denote like elements throughout the figures, and wherein:

FIG. 1 illustrates a prior art of a conventional electric utility metering system having a plurality of customer units attached to a public utility electric source;

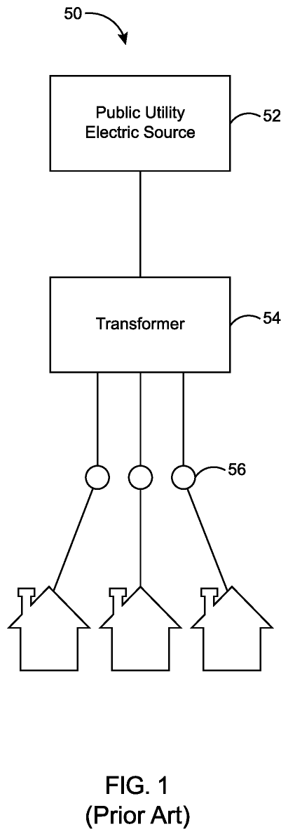

FIG. 2A illustrates a high-level block diagram of an electric utility metering system for detecting and to prevent the theft of electricity in accordance with the preferred embodiment of the present invention;

FIG. 2B illustrates a high level operational block diagram of the electric utility metering system for detecting and to prevent the theft of electricity in accordance with the preferred embodiment of the present invention;

FIG. 2C illustrates a top perspective view of an electric meter housing of the electric utility metering system in accordance with the preferred embodiment of the present invention;

FIG. 2D illustrates a bottom perspective view of the electric meter housing of the electric utility metering system in accordance with the preferred embodiment of the present invention;

FIG. 3 illustrates a block diagram of the electric utility metering system for detecting and to prevent the theft of electricity in accordance with the preferred embodiment of the present invention;

FIG. 4 illustrates a block diagram of the electric utility metering system for detecting and to prevent the theft of electricity in accordance with one embodiment of the present invention; and

FIG. 5 illustrates a flowchart of a method for detecting and to prevent the theft of electricity utilizing the electric utility metering system in accordance with the preferred embodiment of the present invention.

FIG. 6 illustrates a block diagram of an alternative embodiment of the electric utility metering system for detecting and to prevent the theft of electricity.

FIG. 7 illustrates an alternative embodiment of a specialty meter designed for use in the middle of a service span (“mid service span”).

FIG. 8 illustrates another alternative embodiment of a specialty meter designed for mid service span use.

FIG. 9 illustrates an alternative embodiment of an underground electric utility metering system for detecting and to prevent the theft of electricity.

### DETAILED DESCRIPTION OF THE FIGURES

In the following discussion that addresses a number of embodiments and applications of the present invention, reference is made to the accompanying figures that form a part hereof, and in which is shown by way of illustration specific embodiments in which the invention may be practiced. It is to be understood that other embodiments may be utilized, and changes may be made without departing from the scope of the present invention.

Various inventive features are described below that can each be used independently of one another or in combination with other features. However, any single inventive feature may not address any of the problems discussed above or only address one of the problems discussed above. Further, one or more of the problems discussed above may not be fully addressed by any of the features described below.

As used herein, the singular forms “a”, “an” and “the” include plural referents unless the context clearly dictates otherwise. “And” as used herein is interchangeably used with “or” unless expressly stated otherwise. As used herein, the term ‘about” means +/−5% of the recited parameter. All embodiments of any aspect of the invention can be used in combination, unless the context clearly dictates otherwise.

Unless the context clearly requires otherwise, throughout the description and the claims, the words ‘comprise’, ‘comprising’, and the like are to be construed in an inclusive sense as opposed to an exclusive or exhaustive sense; that is to say, in the sense of “including, but not limited to”. Words using the singular or plural number also include the plural and singular number, respectively. Additionally, the words “herein,” “wherein”, “whereas”, “above,” and “below” and words of similar import, when used in this application, shall refer to this application as a whole and not to any particular portions of the application.

The description of embodiments of the disclosure is not intended to be exhaustive or to limit the disclosure to the precise form disclosed. While the specific embodiments of, and examples for, the disclosure are described herein for illustrative purposes, various equivalent modifications are possible within the scope of the disclosure, as those skilled in the relevant art will recognize.

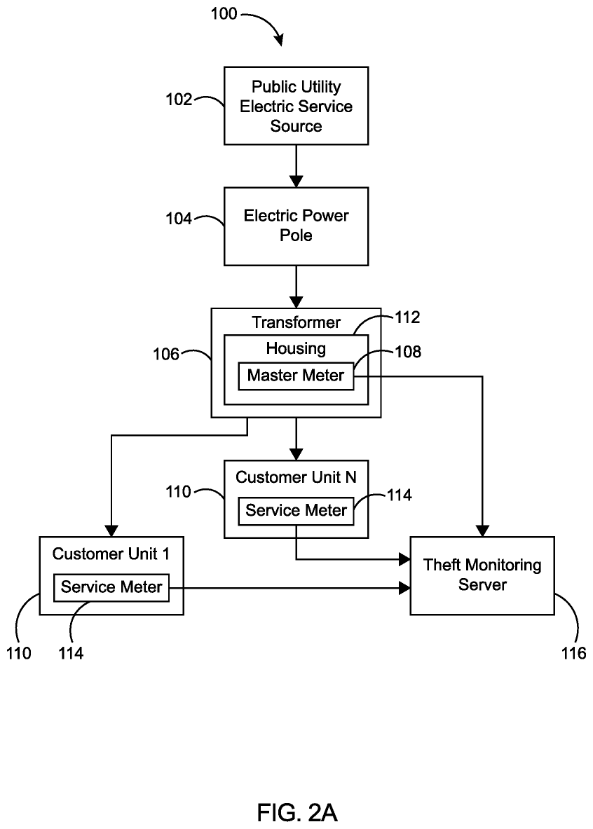

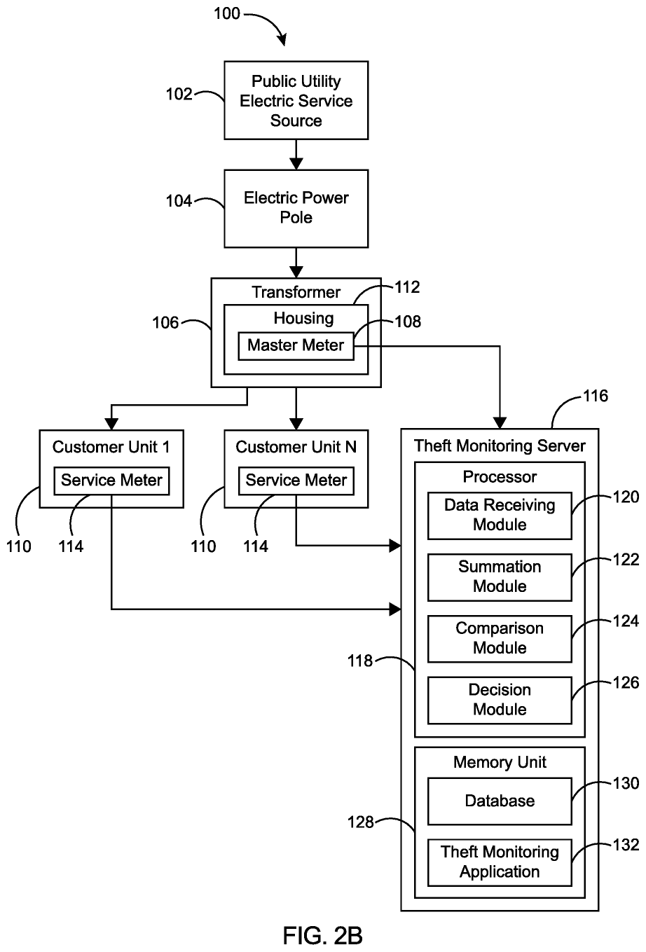

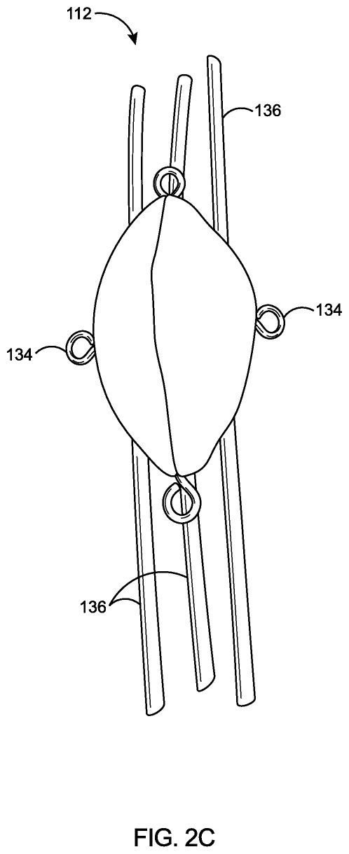

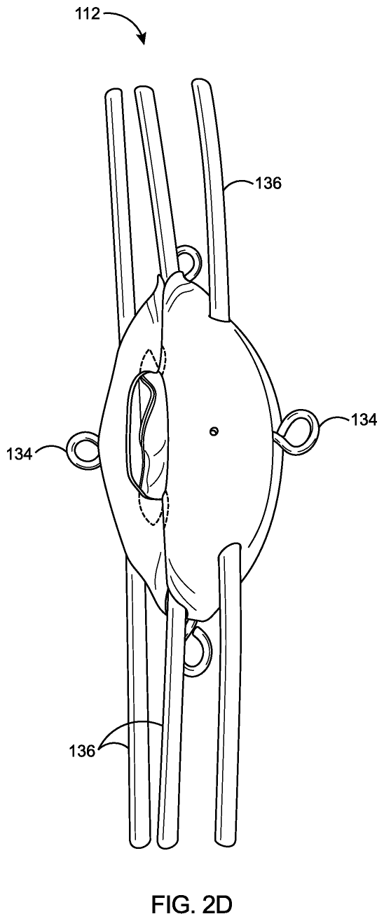

Referring to FIGS. 2A to 2D, a block diagram of an electric utility metering system 100 for detecting and to prevent the theft of electricity in accordance with the preferred embodiment of the present invention is illustrated in FIG. 2A. The present invention provides an electric utility metering system 100 for detecting when electrical meters have been tampered with, to prevent the theft of electricity from meters. The theft of electricity is prevented with an electric meter housing having remotely read electrical meters.

The electric utility metering system 100 comprises a public utility electric service source 102, a transformer 106, a master meter 108 positioned inside an electric meter housing 112, a plurality of public utility customer units 110 connected to the public utility electric service source 102 and a theft monitoring server 116. The public utility electric service source 102 can be a company in the electric power industry that engages in electricity generation and distribution of electricity. Electric power distribution is the final stage in the delivery of electric power which carries electricity from the transmission system to individual consumers through overhead power lines. An electric power pole 104 is used to support overhead power lines and related equipment such as transformers and streetlights which is referred to as a transmission pole. The electric power pole 104 can be made of material selected from a group consisting of: wood, metal, concrete, or composites like fiberglass.

In the present invention, the transformer 106 is embedded with the master meter 108 and electrically connected to the public utility electric service source 102 via the overhead power lines supported by the electric power pole 104. The master meter 108 is positioned inside the electric meter housing 112 having a plurality of bolts 134 and a plurality of connecting wires 136 molded into it as illustrated in FIG. 2C and FIG. 2D. The housing 112 is intended to be used on electric power poles 104 and connects to the utility transformer 106 or the customer's service wires at the electric power pole 104. The plurality of bolts 134 is employed to attach the electric meter housing 112 having the master meter 108 with a plurality of service wires 136 or to attach the housing 112 with the electric power pole 104 when needed. The plurality of connecting wires 136 is employed for attaching 112 the housing with the transformer 106 or with the plurality of service wires. The housing 112 is made of injection molded plastic. The transformer 106 embedded with the master meter 108 may be positioned on the electric power pole 104 or can be secured by a pad-mount 330 which prevents accessing the master meter 108 by thieves.

The transformer 106 reduces the primary voltage of the public utility electric service source 102 to the utilization voltage serving the plurality of public utility customer units 110. For example, a distribution transformer constructed with two or more windings may be used to transfer alternating-current electric power by electromagnetic induction from one circuit to another at the same frequency but with different values of voltage and current. The master meter 108 is configured to record the total electric power before distribution to each of the plurality of public utility customer units 110. The plurality of public utility customer units 110 can be, for example, 1 though “n” number customer units connected with the public utility electric service source 102. The master meter 108 is a smart meter, which can preferably be an electricity meter that can digitally send meter readings to the theft monitoring server 116. The smart meter of the present invention does not have blades or readout. This prevents the intruders or thieves from tampering the meter depending on the reading on the meter. Since there is not readout or display thieves cannot know the actual reading or amount of electricity consumed and hence cannot understand whether to tamper the meter and steal electricity. The smart meter uses a secure national communication network to automatically and wirelessly send the meter readings on a regular basis to the theft monitoring server 116. The smart meter of the present invention records consumption of electrical energy for definite intervals of time and communicates that information to the theft monitoring server 116.

The plurality of public utility customer units 110 is configured to measure the quantity of electricity utilized by each of the customers. Each of the plurality of public utility customer units 110 includes a standard service meter 114 to measure or record the amount of electricity utilized by each customer unit. The standard service meter 114 is also a smart meter, which can preferably be an electricity meter that can digitally send meter readings to the theft monitoring server 116. The standard service meter 114 on each of the plurality of public utility customer units 110 and the master meter 108 embedded on the transformer 106 communicates with the theft monitoring server 116.

The theft monitoring server 116 can be a general purpose computer located somewhere on the premises or remotely and is programmed with software that is used to detect and prevent the theft of electricity. The electric utility metering system 100 includes the theft monitoring server 116 residing on a central computer (not shown) having a processor 118 installed with a theft monitoring application 132 and coupled with a memory unit 128 integrated with a central database 130 as illustrated in FIG. 2B. The theft monitoring server 116 comprises a data receiving module 120, a summation module 122, a comparison module 124 and a decision module 126 located at the processor 118 of the theft monitoring server 116. The data receiving module 120 is configured to receive and store meter readings from the master meter 108 and the standard service meter 114 on each of the plurality of public utility customer units 110, 112. The summation module 122 is configured to add the meter readings received from the standard service meter 114 on each of the plurality of public utility customer units 110 to get a total power consumed by the plurality of public utility customer units 110. The comparison module 124 is configured to compare the meter readings from the master meter 108 with the total power consumed by the plurality of public utility customer units 110. The comparison module 124 compares the meter readings from the master meter 108 with the total power consumed. If the meter readings from the master meter 108 and the total power consumed are the same, then no theft occurred. If the meter readings from the master meter 108 exceeds the total power consumed by the plurality of public utility customer units 110 then a theft in electricity occurred The decision module 126 is configured to provide a decision on whether the theft of electricity occurred or not.

The theft monitoring application 132 is stored on the memory unit 128 of the electric utility metering system 100. The memory unit 128 is, for example, a random-access memory (RAM) or another type of dynamic storage device that stores information and instructions for execution by the processor 118. The memory unit 128 also stores temporary variables and other intermediate information used during execution of the instructions by the processor 118. The electric utility metering system 100 further comprises a read only memory (ROM) or another type of static storage device that stores static information and instructions for the processor 118.

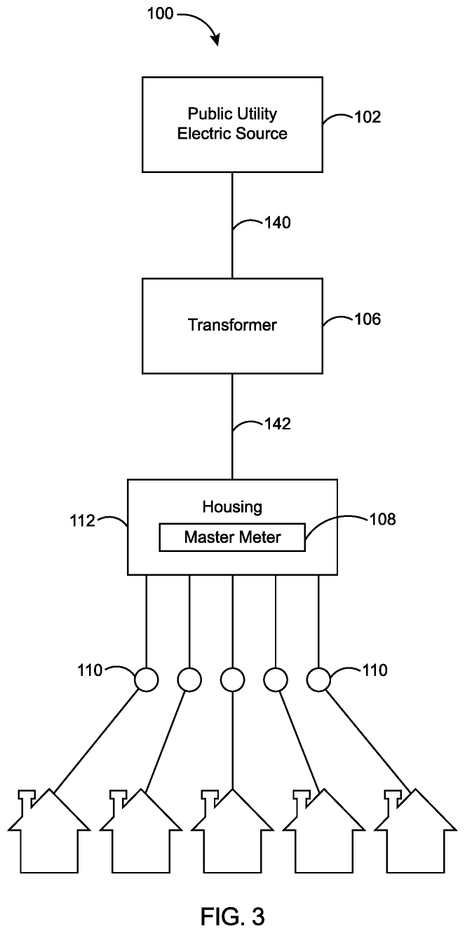

FIG. 3 illustrates a block diagram of the electric utility metering system for detecting and to prevent the theft of electricity in accordance with the preferred embodiment of the present invention. The public utility electric service source 102 is connected to the transformer 106 by means of a primary level wire 140 and the transformer 106 is then connected to the master meter 108 by means of the secondary level wire 142 as illustrated in FIG. 2. The transformer 106 may be positioned high on the electric pole or may be secured via a pad-mount. The plurality of public utility customer units 110 is connected to the master meter 108. The master meter 108 is positioned inside the electric meter housing (not shown) and is not accessible to customers. The plurality of public utility customer units 110 for example, 1 to “N” customer units are connected to the master meter 108 to measure individual electrical energy consumed by each of the plurality of customer units 110.

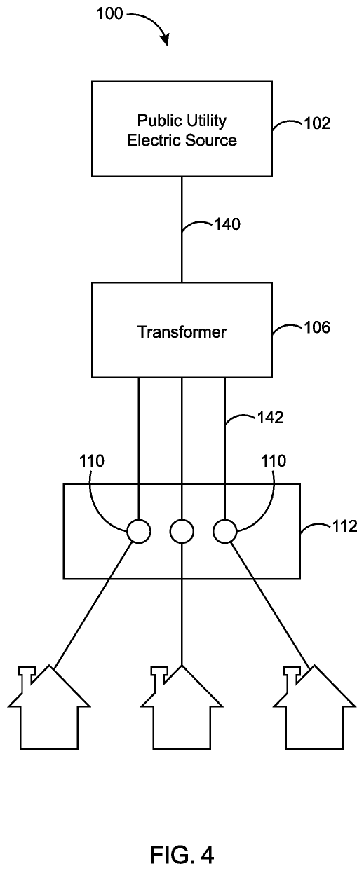

FIG. 4 illustrates a block diagram of the electric utility metering system for detecting and to prevent the theft of electricity in accordance with one embodiment of the present invention. In this embodiment, each of the plurality of public utility customer units 110 may be positioned inside the electric meter housing 112. The plurality of public utility customer units 110 may be meters utilized for measuring electrical energy consumed by each customer. As the plurality of public utility customer units 110 are positioned inside the electric meter housing 112, the customers are unable to access the customer units 110 and thus prevent stealing of electricity.

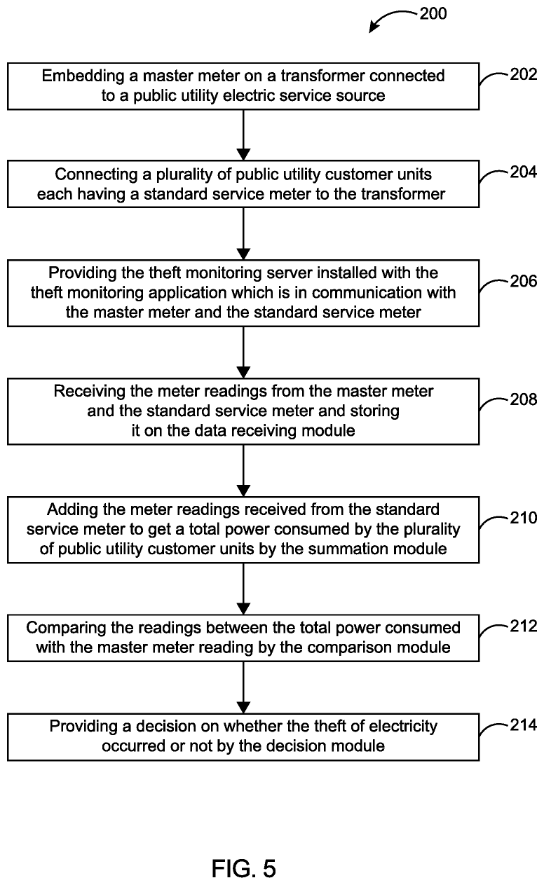

FIG. 5 illustrates a flowchart of a method 200 for detecting and to prevent the theft of electricity utilizing the electric utility metering system in accordance with the preferred embodiment of the present invention. The method 200 comprises the steps of embedding a master meter on a transformer connected to a public utility electric service source through an electric power pole as indicated in block 202. Connecting a plurality of public utility customer units to the transformer, each of the plurality of public utility customer units having a standard service meter as indicated in block 204. As indicated in block 206, providing a theft monitoring server installed with a theft monitoring application which is in communication with the master meter and the standard service meter on each of the plurality of public utility customer units. Then receiving and storing the meter readings from the master meter and the standard service meter on each of the plurality of public utility customer units on the data receiving module as indicated in block 208. As indicated in block 210, adding the meter readings received from the standard service meter on each of the plurality of public utility customer units to get a total power consumed by the plurality of public utility customer units by the summation module. Comparing the meter readings from the master meter with the total power consumed by the plurality of public utility customer units by the comparison module as indicated in block 212. If the meter readings from the master meter and the total power consumed are the same, then no theft occurred. If the total power consumed is less than the meter readings from the master meter, then a theft in electricity occurred. Providing a decision on whether the theft of electricity occurred or not by the decision module as indicated in block 214.

In one embodiment, a non-transitory computer-readable medium comprises computer-executable instructions stored therein for causing a computer to implement a program executable on the electric utility metering system 100 for detecting when electrical meters have been tampered with to prevent the theft of electricity from meters with electric meter housings using a remotely read electrical meter. The non-transitory computer readable storage medium comprises a USB memory, CD-ROM, flexible disc, DVD or a flash memory. In one embodiment, a non-transitory computer-readable medium comprises computer-executable instructions stored therein for causing mobility solutions to implement a program executable on the electric utility metering system 100 that prevent theft of electricity utilizing the theft monitoring application 132.

An embodiment of the present invention relates to a computer storage product with a computer-readable medium having computer code thereon for performing various computer-implemented operations. The media and computer code may be those specially designed and constructed for the purposes of the present invention, or they may be of the kind well known and available to those having skill in the computer software arts. Examples of computer-readable media include, but are not limited to: magnetic media such as hard disks, floppy disks, and magnetic tape; optical media such as CD-ROMs, DVDs and holographic devices; magneto-optical media; and hardware devices that are specially configured to store and execute program code, such as application-specific integrated circuits (“ASICs”), programmable logic devices (“PLDs”) and ROM and RAM devices. Examples of computer code include machine code, such as produced by a compiler, and files containing higher-level code that are executed by a computer using an interpreter. For example, an embodiment of the invention may be implemented using Java, C++, or other object-oriented programming language and development tools. Another embodiment of the invention may be implemented in hardwired circuitry in place of, or in combination with, machine-executable software instructions.

It should also be understood that logic codes, programs, modules, processes, methods and the order in which the respective processes of each method are performed are purely exemplary. Depending on implementation, the processes or any underlying sub-processes and methods may be performed in any order or concurrently, unless indicated otherwise in the present disclosure. Further, unless stated otherwise with specificity, the definition of logic code within the context of this disclosure is not related or limited to any particular programming language and may comprise one or more modules that may be executed on one or more processors in distributed, non-distributed, single or multiprocessing environments.

Certain embodiments are disclosed with reference to flowchart illustrations or block diagrams of methods, apparatus (systems) and computer program products according to embodiments. It will be understood that each block of the flowchart illustrations or block diagrams, and combinations of blocks in the flowchart illustrations and/or block diagrams, may be implemented by computer program instructions. These computer program instructions may be provided to a processor of a general purpose computer, a special purpose machinery, or other programmable data processing apparatus to produce a machine, such that the instructions, which execute via the processor of the computer or other programmable data processing apparatus, create means for implementing the functions or acts specified in the flowchart or block diagram block or blocks.

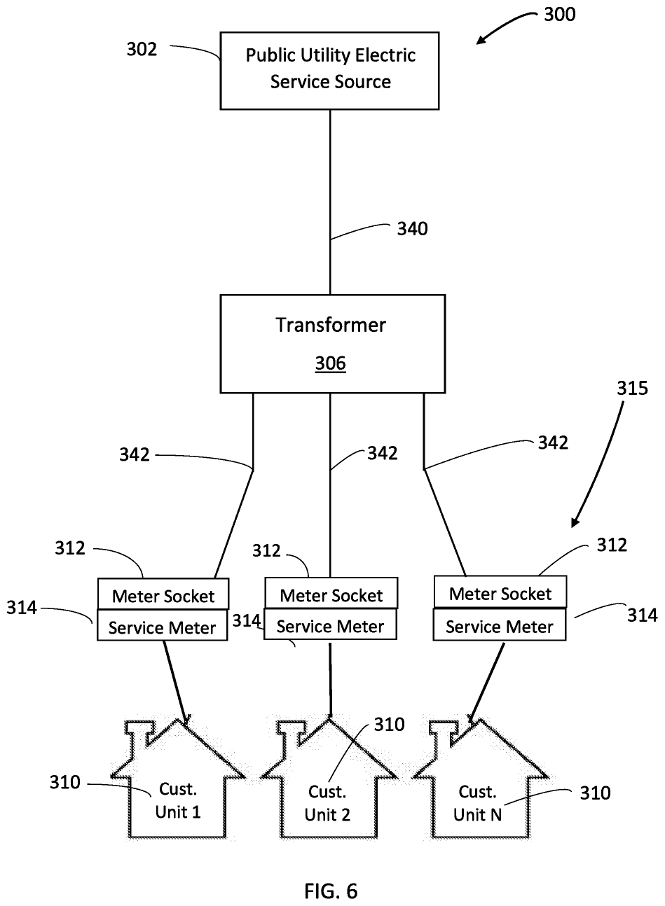

FIG. 6 illustrates a block diagram of an alternative embodiment 300 of the electric utility metering system for the prevention of the theft of electricity. The electric utility metering system 300 comprises a public utility electric service source 302, a transformer 306, a meter socket 312, a service meter (“meter”) 314 and a plurality (one or more) of public utility customer units 310 operatively connected to the public utility electric service source 302. An electric service source 302 can be an electric power pole, an aerial cable, and the like. The electric service source 302 is connected to the transformer 306 using a primary lead wire 340 and the transformer 306 is connected a meter socket 312 using a service wire 342. Those of ordinary skill in the art will understand that “primary lead wire” and “service wire” are sometimes used in the singular form in the industry, but both primary lead wire 340 and service wire 342 can include multiple wires. The plurality (one or more) of public utility customer units 310 is configured to measure the quantity of electricity consumed by each of the customers. Each of the plurality of public utility customer units 310 includes a meter 314 to measure or record the amount of electricity utilized by each customer unit 310. The meter 314 can also be a smart meter with automated meter-reading. It should be noted that FIG. 6 presents the transformer 306 having a service span 315 connecting it to each customer unit 310. In this case the service span 315 comprises includes the entire connection between the transformer 306 and the customer unit 310. Alternatively, there could be a single electrical line (not shown) coming from the transformer 306 which would later branch into multiple service spans.

The meter 314 and meter socket 312 are suspended in a service span 315 between the transformer 306 and a customer unit 310. In this description and the accompanying claims, it is to be understood that “service span” refers to electrical wiring between the transformer 306 and a single particular customer unit 310. The suspended meter socket 312 can be a standard meter socket in the industry with wires or hardware included in its structure to enable it to be installed in the service span 315. For example, the meter socket 312 can have attachment points to accept structural wires (e.g. ground, neutral, support). As will be understood by those of ordinary skill, attachment points or strain wires can be employed to connect wires under physical load or strain by splicing, crimping, preforms, or similar hardware. Further, the meter socket 312 can employ conductor wires or other attachment points to accept the wires that conduct electricity to the customer unit 310. The conductor wires can be connected by splicing, crimping, preforms, or similar hardware.

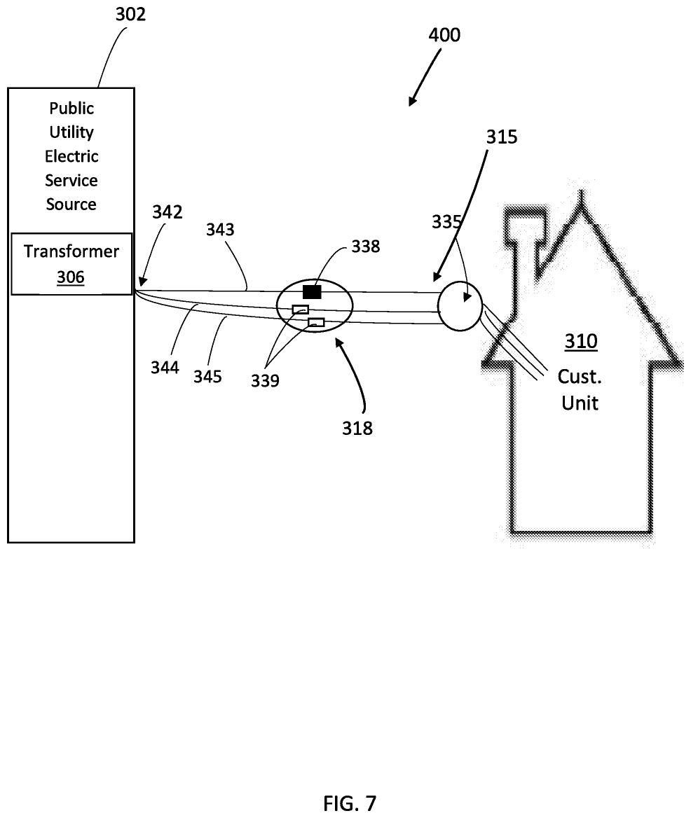

FIG. 7 illustrates an alternative embodiment 400 of a specialty meter 318 designed for use in the middle of a service span 315 (“mid service span”). The specialty meter 318 can be a smart meter enabling automated reading. The specialty meter 318 can be smaller than a standard meter size, and it is enclosed and protected from the elements. The specialty meter 318 is encased and cannot be read by a user (person) without visual assistance. “Visual assistance” can include visually reading the specialty meter 318 with binoculars, from a bucket truck, or by climbing an electric power pole 302. In a further embodiment, the specialty meter 318 cannot be read visually at all, but rather must be read by automated meter reading technology.

In the embodiment 400 of an electric utility metering system shown in FIG. 7, a transformer 306 is mounted to a public utility electric service source (electric power pole) 302. In this example, the service wire 342 includes a neutral wire 343, and two electrical hot wires 344, 345. The neutral wire 343 can be bare while the electrical conductor (“hot”) wires 344, 345 are insulated. The neutral wire 343 can be a load bearing structural wire for providing structural support in contrast to the hot wires 344, 345. It should be noted that FIG. 7 depicts hot wires 344, 345 and neutral wire 343 separately as these wires are electrically separate. In terms of construction or installation these three wires would generally appear as a single wire, generally as a twisted bundle. The specialty meter 318 is installed mid service span 315 and includes an attachment point 338 to secure the meter to the neutral wire 343. Attachment points or strain wires can be employed to connect wires under physical load or strain by splicing, crimping, preforms, or similar hardware. The specialty meter 318 can also employ attachment points 339 or conductor wires to accept the wires 334 and 335 that conduct electricity to the customer unit 310. The attachment points 339 or conductor wires can be connected by splicing, crimping, preforms, or similar hardware. A service connection point 335 is shown routing the service wire 342 to the customer unit 310. For illustrative purposes, only one customer unit 310 is shown in FIG. 7 but it will be understood that a single transformer 306 can have service wires 342 providing electricity to several customer units 310, as shown in FIG. 6. Along the service span 315, specialty meters 318 can be installed for each customer unit 310.

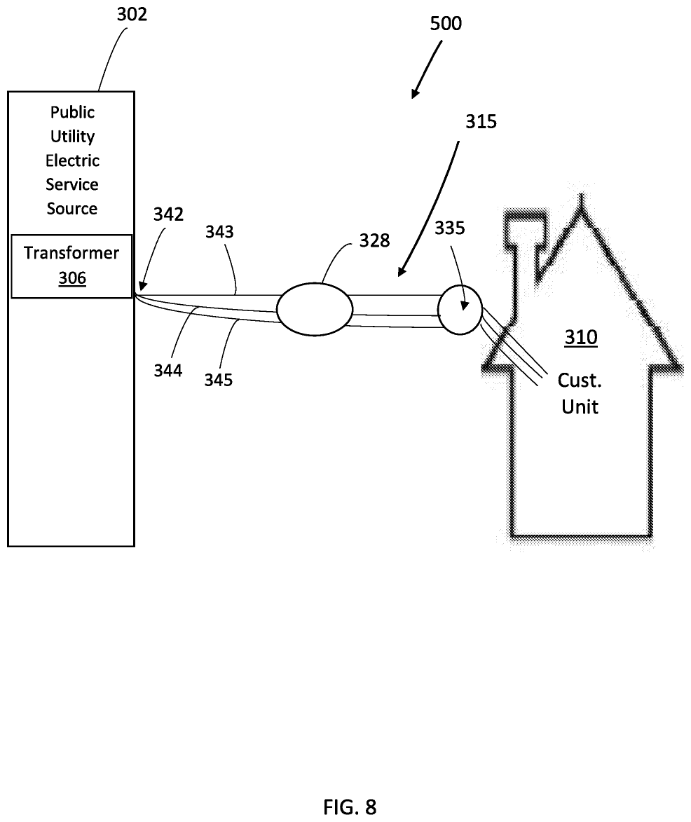

FIG. 8 illustrates an alternative embodiment 500 of a specialty meter 328 designed for mid service span 315 use. The specialty meter 328 resembles a “clamshell” and encloses the all of the service wires 342. The clamshell specialty meter 328 can be affixed (clamped) around the to the service wires 342 and measure electrical usage directly from the electrical conductor wires 344, 345. One implementation for measuring electrical usage can include the specialty meter 328 piercing through insulation around the electrical conductor wires 344, 345. Another implementation for measuring electrical usage can include measuring the magnetic field around the conductor wires 344, 345. One of the advantages of the clamshell specialty meter 328 is the ease of installation, because it can be installed and suspended at any location along the service span 315.

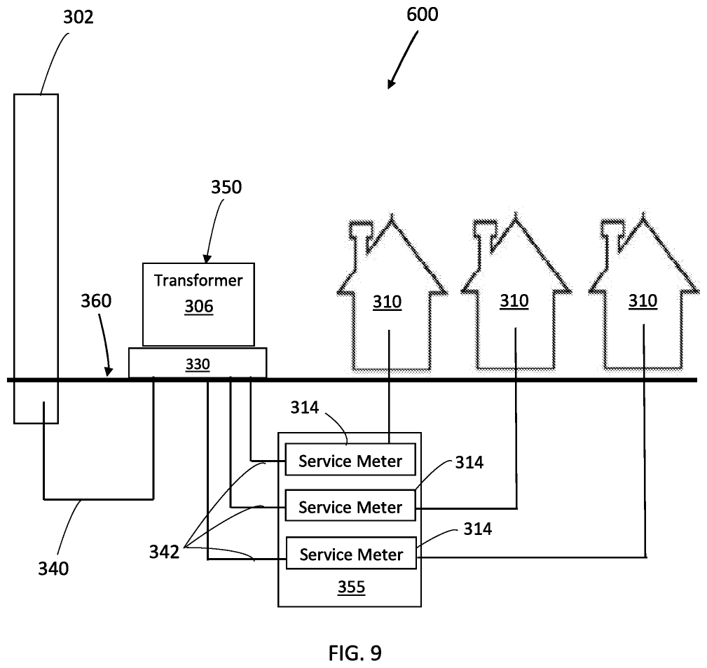

FIG. 9 illustrates an alternative embodiment 600 of an underground electric utility metering system for preventing the theft of electricity. A public utility electric service source 302 is connected to the transformer 306 using a primary lead wire 340. The transformer 306 is encased in a housing 350 (“housing” is used in this context as a general structure to house components as opposed to electric meter housings) and in this example is a pad-mounted transformer 306. The pad 330 rests on top of the ground surface 360. The transformer 306 is connected to a service meter 314 using a service wire 342. The service wires 342 are routed under the ground surface 360 and connect to meters 314 encased in a cabinet 355 which may be optionally located underground. The plurality (one or more) of public utility customer units 310 is configured to measure the quantity of electricity consumed by each of the customers. Each of the plurality of public utility customer units 310 includes a meter 314 to measure or record the amount of electricity utilized by each customer unit 310. The meter 314 can be a smart meter enabling automated reading or it can be a meter that requires visual reading by opening the cabinet 355. Preferably, the meters 314 are encased in a cabinet 355. The cabinet 355 may optionally be located underground. Alternatively, the cabinet 355 enclosing the meters 314 could be located in the same housing 350 as the transformer 306. Under a further alternative embodiment, the cabinet 355 may be located adjacent to the housing 350 holding the transformer 306. “Housing” here is used in this context as a general structure to house components. This should not be confused with electric meter housings. In still another alternative embodiment, the meters 314 may be co-located with the transformer 306 in the housing 350. In that case, there would be no need for a cabinet.

The foregoing description of the embodiments of the present invention has been presented for the purpose of illustration and description. It is not intended to be exhaustive or to limit the invention to the precise form disclosed. Many modifications and variations are possible in light of the above teachings. It is intended that the scope of the present invention is not limited by this detailed description.

What is claimed is:

1. An electric utility metering system for preventing theft of electricity comprising:
a. a public utility electric service source;
b. a transformer electrically connected to the public utility electric service source through a primary lead wire;
c. a meter electrically connected to the transformer through a service wire;
d. the meter is electrically connected to a public utility customer unit through the service wire;
e. a meter socket;
f. the meter is installed in the meter socket; and
g. the meter and the meter socket are suspended in a service span between the public utility electric service source and the public utility customer unit.

2. The system of claim 1 wherein the meter socket comprises:
a. attachment points for connecting structural wires under physical load or strain; and
b. attachment points for connecting electrically conducting wires that transfer electricity from the public utility electric service source through the meter to the public utility customer unit.

3. The system of claim 1 wherein the meter is a smart meter enabling automated reading, the smart meter further comprising attachment points for connecting electrically conducting wires that transfer electricity from the public utility electric service source, through the smart meter, to the public utility customer unit.

4. An electric utility metering system for preventing theft of electricity comprising:
a. a public utility electric service source;
b. a transformer electrically connected to the public utility electric service source through a primary lead wire;
c. a specialty meter electrically connected to the transformer through a service wire;
d. the specialty meter is a smart meter enabling automated reading;
e. the specialty meter cannot be read by a user without visual assistance;
f. the specialty meter is electrically connected to a public utility customer unit through a service wire;
g. the specialty meter is installed in a service span between the public utility electric service source and the customer unit;
h. attachment points for connecting structural wires under physical load or strain; and
i. attachment points for connecting electrically conducting wires that transfer electricity from the public utility electric service source, through the specialty meter, to the public utility customer unit.

5. An electric utility metering system for preventing theft of electricity comprising:
a. a public utility electric service source;
b. a transformer electrically connected to the public utility electric service source through a primary lead wire;
c. a specialty meter clamped around the service wire, the specialty meter being capable of measuring electrical usage; and
d. the specialty meter is electrically connected to a public utility customer unit through the service wire.

6. An electric utility metering system for preventing theft of electricity when underground construction methods are used, the system comprises:
a. a public utility electric service source;
b. a housing containing a transformer;
c. the transformer is electrically connected to the public utility electric service source through a primary lead wire;
d. a meter electrically connected to the transformer through a first underground service wire;
e. the meter is encased in a cabinet; and
f. the meter is electrically connected to a public utility customer unit via a second underground service wire.

7. The system of claim 6, wherein the cabinet is located underground.

8. The system of claim 6 wherein the meter is co-located with the transformers in the housing.

9. The system of claim 6 wherein the meter is encased in a meter socket.

10. The system of claim 6 wherein the meter is a smart meter enabling automated reading.

11. The system of claim 6 wherein the meter can only be read by a user by opening the cabinet.

12. The system of claim 6, wherein the transformer comprises a pad-mounted transformer.

13. An electric utility metering system for preventing theft of electricity when underground construction methods are used, the system comprises:
a. a public utility electric service source;
b. a housing containing a transformer;
c. the transformer is electrically connected to the public utility electric service source through a primary lead wire;
d. a meter electrically connected to the transformer through a first underground service wire;
e. wherein the meter is co-located with the transformers in the housing; and
f. the meter is electrically connected to a public utility customer unit via a second underground service wire.
